(19) United States
(12) Patent Application Publication
(10) Pub. No.: US 2004/0195583 A1
(43) Pub. Date: Oct. 7, 2004

(54) Election gun assembly resistor and cathode ray tube

(76) Inventors: Yoshihisa Kaminaga, Minato-Ku (JP); Noriyuki Miyamoto, Kamifukuoka-Shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/830,036

(22) Filed: Apr. 23, 2004

Related U.S. Application Data
(63) Continuation of application No. PCT/JP03/10530, filed on Aug. 20, 2003.

(30) Foreign Application Priority Data
Aug. 20, 2002 (JP) 2002-238883
Oct. 16, 2002 (JP) 2002-301942

(51) Int. Cl. H01L 29/74

(52) U.S. Cl. 257/154

(57) ABSTRACT

An electron gun assembly resistor divides a voltage based on a predetermined voltage division ratio and permits a divided voltage to be applied to an electrode of an electron gun assembly. The electron gun assembly resistor is provided with an insulating substrate, a plurality of electrode elements formed on the insulating substrate, a resistor element having a pattern which connects the electrode elements together and which provides a predetermined resistance value, an insulating coating layer which covers the resistor element, and a plurality of metallic terminals connected to the electrode elements, respectively. The metallic terminals are arranged without exposing the electrode elements. The insulating coating layer covers the peripheries of the metallic terminals and are located away from the electrode elements.

### CROSS-REFERENCE TO RELATED APPLICATIONS

This is a Continuation Application of PCT application Ser. No. PCT/JP03/10530, filed Aug. 20, 2003, which was not published under PCT Article 21(2) in English.

This application is based upon and claims the benefit of priority from prior Japanese Patent Applications No. 2002-238883, filed Aug. 20, 2002; No. 2002-301942, filed Oct. 16, 2002, the entire contents of both of which are incorporated herein by reference.

### BACKGROUND OF THE INVENTION

1. Field of the Invention

The present invention relates to an electron gun assembly resistor employed in a cathode ray tube. More specifically, the present invention relates to an electron gun assembly resistor used for applying the grid electrodes of an electron gun assembly with voltages divided based on a predetermined voltage division ratio, and a cathode ray tube incorporating this resistor.

2. Description of the Related Art

In general, a cathode ray tube, which is used for example as a color television receiver, comprises an electron gun assembly for emitting electron beams toward a panel. The electron gun assembly has a number of grid electrodes. These grid electrodes are provided independently of an anode applied with an anode voltage, and relatively high voltages are applied to the grid electrodes.

In order to apply a high voltage to each grid electrode from a stem portion, the cathode ray tube of the above configuration has to be designed to solve a withstand voltage problem. To solve this problem, the cathode ray tube incorporates a voltage-dividing resistor together with the electron gun assembly. The voltage-dividing resistor is used as an electron gun assembly resistor (hereinafter referred to simply as a resistor). The resistor divides the anode voltage based on a predetermined voltage division ratio, and desired high voltages are applied to them.

The resistor comprises an electrode element and a resistor element, both provided on an insulating board. The electrode element is formed of a material having low resistance, while the resistor element is formed of a material being similar to that of the electrode element but having high resistance. The resistor element and part of the electrode element are covered with an insulating coating layer. A terminal section including a metallic terminal is electrically connected to the electrode element and is fixed inside a through-hole formed in the insulating board.

The cathode ray tube, to which a high voltage is applied as described above, is subject to withstand voltage treatment in the manufacturing process, so as to improve the withstand voltage characteristics. In the withstand voltage treatment, a high, pulsed AC voltage whose peak voltage (60 to 70 kV) is twice to three times as high as a normal operating voltage, is applied. This causes electric discharge, and it serves to remove burrs, attachments to the grid electrodes, or other undesirable matter that may deteriorate the withstand voltage characteristics.

A triple junction is formed in a resistor disposed in the vacuum because the edge of the electrode element is covered with the insulating coating layer. When a high voltage is applied to the cathode ray tube, an electric field is generated concentratedly at the edge of the electrode element. As a result, in the neighborhood of the triple junction, electrons and positive ions react intensively because of the gas adsorbed on the material surfaces of the components inside the cathode ray tube. The bombardment causes exfoliation of part of the electrode element. In addition, in the neighborhood of the triple junction, not only the electrode element but also the insulating coating layer located above it may undergo exfoliation.

The exfoliated pieces of the members float in the interior of the cathode ray tube, clogging the apertures of the shadow mask. If the electrode elements exfoliate, even a resistor element connected to them may be damaged. In the worst case, the resistor element may break. If the electrode elements exfoliate, electric discharge may occur, with the remaining parts as a cathode point, when the cathode ray tube operates. This may cause a focusing error of the cathode ray tube, because an excessive amount of current flows to a grid electrode when this electrode is applied with a voltage through the resistor. As a result, a desired voltage cannot be applied to this grid electrode in a stable manner.

As described above, the conventional cathode ray tube has problems in that the edge of the electrode element may exfoliate, the resistor element may break, and the part of the electrode element that remains after the edge exfoliation may cause electric discharge.

In an effort to solve these problems, Jpn. Pat. Appln. KOKAI Publication No. 6-68811 proposes covering the edge of an electrode element with an insulation layer, which is thinner than the portion away from the electrode element. In a cathode ray tube of this structure, however, the electrode element is located under the thin insulation layer, a triple junction is inevitably formed, and part of the electrode element may exfoliate during the withstand voltage treatment. It is therefore not possible to solve all problems described above.

### BRIEF SUMMARY OF THE INVENTION

The present invention has been made in consideration of the above problems, and an object of the present invention is to provide an electron gun assembly resistor which is not damaged even when a high voltage is applied and is therefore reliable in practical use, as well as a cathode ray tube incorporating the electron gun assembly resistor.

An electron gun assembly resistor according to the first aspect of the present invention comprises:

an insulating substrate;

a plurality of electrode elements formed on the insulating substrate and looking like islands;

a resistor element connecting the electrode elements together and providing a predetermined resistance value; and

a plurality of metallic terminals which include flanges in contact with the electrode elements, and which are therefore connected to the electrode elements,

the electron gun assembly resistor satisfying

L1≦L2,

where L1 is an outer dimension of at least one of the electrode elements, and L2 is an outer dimension of the flange of the metallic terminal that is connected to the electrode element whose outer dimension is L1.

A cathode ray tube according to the second aspect of the present invention comprises:

a face panel;

a funnel integrally connected to the face panel;

a phosphor screen formed on an inner surface of the face panel;

an electron gun assembly arranged in a neck of the funnel, configured to emit electron beams toward the phosphor screen, and including a plurality of grid electrodes; and

an electron gun assembly resistor arranged in the neck and juxtaposed to the electron gun assembly, the electron gun assembly resistor dividing a voltage based on a predetermined voltage division ratio and permitting a divided voltage to be applied to at least one of the grid electrodes, the electrode gun assembly resistor comprising:

an insulating substrate;

a plurality of electrode elements formed on the insulating substrate and looking like islands;

a resistor element connecting the electrode elements together and providing a predetermined resistance value; and

a plurality of metallic terminals which include flanges in contact with the electrode elements, and which are therefore connected to the electrode elements,

the electron gun assembly resistor satisfying

L1≦L2,

where L1 is an outer dimension of at least one of the electrode elements, and L2 is an outer dimension of the flange of the metallic terminal that is connected to the electrode element whose outer dimension is L1.

The electrode gun assembly resistor and the cathode ray tube describe above are advantageous in that a discharge current, which may be generated when glow discharge occurs, is prevented from flowing to the electrode elements. Hence, an electrical breakdown of the electrode elements is prevented, and reliable characteristics are ensured.

An electron gun assembly resistor according to the third aspect of the present invention divides a voltage based on a predetermined voltage division ratio and permits a divided voltage to be applied to an electrode of an electron gun assembly, the electron gun assembly resistor comprising:

an insulating substrate;

a plurality of electrode elements formed on the insulating substrate;

a resistor element connecting the electrode elements together and providing a predetermined resistance value;

an insulating coating layer which covers the resistor element; and

a plurality of metallic terminals connected to the electrode elements, respectively,

the metallic terminals being arranged without exposing the electrode elements,

the insulating coating layer covering peripheries of the metallic terminals and being located away from the electrode elements.

In the electron gun assembly resistor, the metallic terminals are arranged without exposing the electrode elements. With this structure, the peripheral portions or the edges of the electrode elements are not projected from under the metallic terminals. In addition, the insulating coating layer is not in contact with the electrode elements; it is located away from the electrode elements. Even if high voltage is applied in the high vacuum state, no triple junction is formed, and the electrode elements do not produce a region where an electric field is generated concentratedly. The electrode elements and the insulating coating layer are prevented from exfoliating, and damage to the resistor element connected to the electrode elements is also prevented. Furthermore, if the electrode elements should exfoliate, the remaining portions of the electrode elements do not cause electrical discharge.

In the electron gun assembly resistor of the present invention, the insulating coating layer covers peripheries of the metallic electrodes covering the electrode elements. With this structure, the exposed portion of the insulating substrate is reduced in area. It should be noted that the insulating substrate emits secondary electrons and promotes electrical discharge when it is bombarded with floating electrodes. Therefore, electrical discharge can be suppressed by covering the surface of the insulating substrate, from which secondary electrons are emitted, with the insulating coating layer.

### BRIEF DESCRIPTION OF THE SEVERAL VIEWS OF THE DRAWING

FIG. 1 schematically illustrates a color cathode ray tube apparatus according to one embodiment of the present invention.

FIG. 2 schematically illustrates an electron gun assembly applied to the color cathode ray tube apparatus shown in FIG. 1.

FIG. 3 is a perspective view illustrating an electron gun assembly resistor applied to the electron gun assembly of FIG. 2, the electron gun assembly resistor being viewed from above the insulating coating layer constituting the outer surface.

FIG. 4 shows how terminal B and its neighboring region are when the electron gun assembly resistor of the first embodiment is taken along line X-X′ of FIG. 3.

FIG. 5 illustrates advantages of the first embodiment and shows how many defects are produced when the electron gun assembly resistor is subjected to a forcible degausser test.

FIG. 6 shows how terminal B and its neighboring region are when the electron gun assembly resistor, which is of the first embodiment but has a different structure, is taken along line X-X′ of FIG. 3.

FIG. 7 shows how terminal B and its neighboring region are when an electron gun assembly resistor of the second embodiment is taken along line X-X′ of FIG. 3.

FIG. 8 illustrates advantages of the second embodiment and shows how many defects are produced when the electron gun assembly resistor is subjected to withstand voltage treatment.

### DETAILED DESCRIPTION OF THE INVENTION

An electron gun assembly resistor (hereinafter referred to simply as a “resistor”) according to one embodiment of the present invention will now be described with reference to the drawings.

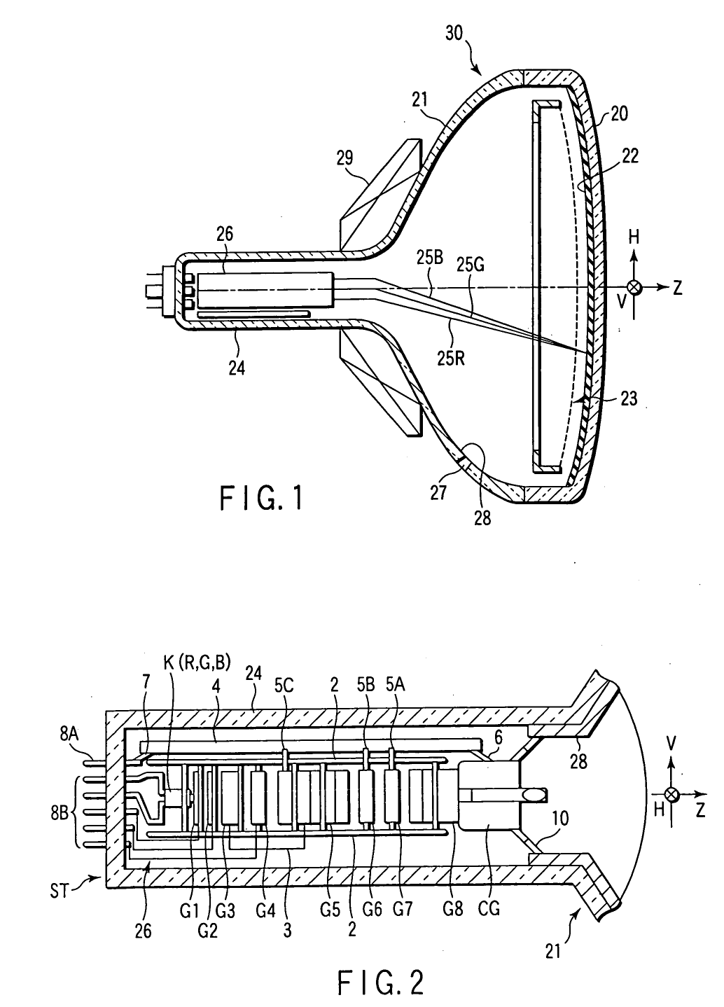

As shown in FIG. 1, a color cathode ray tube apparatus, which is one example of a cathode ray tube apparatus, comprises a vacuum envelope 30. The vacuum envelope 30 includes a face panel 20 and a funnel 21 integrally coupled to the face panel 20. The face panel 20 is substantially rectangular and has a phosphor screen 22 on the inner surface. The phosphor screen 22 has phosphor layers corresponding to three colors. The phosphor layers are in the form of stripes or dots and emit blue light, green light and red light. A shadow mask 23 faces the phosphor screen 22 and has a large number of electron beam passage holes (apertures).

An in-line type electron gun assembly 26 is arranged in a cylindrical neck 24, which is a small-diameter portion of the funnel 21. The electron gun assembly 26 emits three electron beams 25B, 25G and 25R which travel toward the phosphor screen 22 in the direction of the tube axis, i.e., in the Z-axis direction. The three electron beams include a center beam 25G and a pair of side beams 25B and 25R, and these beams are in the same plane and aligned in the horizontal direction, i.e., in the H-axis direction.

An anode terminal 27, by which a high voltage is applied, is provided for the funnel 21. An internal conductive film 28 made of graphite and connected to the anode terminal 27 is formed on the inner surface of the funnel 21. A deflection yoke 29 is provided outside of the funnel 21. The deflection yoke 29 generates a nonuniform deflecting magnetic field for deflecting the three electron beams 25B, 25G and 25R emitted from the electron gun assembly 26. The deflection yoke 29 includes a horizontal deflection coil for generating a pincushion-type horizontally deflecting magnetic field and a vertical deflection coil for generating a barrel-type vertically deflecting magnetic field.

In the color cathode ray tube apparatus of the above structure, the three electron beams 25B, 25G and 25R emitted-from the electron gun assembly 26 converge and are focused on the corresponding phosphor layers of the phosphor screen 22. The three electron beams 25B, 25G and 25R falling on the phosphor screen 22 are deflected by the nonuniform magnetic field the deflection yoke 29 generates. In other words, the three electron beams 25B, 25G and 25R are scanned across the phosphor screen 22 in the horizontal direction H and the vertical direction V. As a result, the phosphor screen 22 displays a color image.

As shown in FIG. 2, the electron gun assembly 26 includes three cathodes K (R,G,B) aligned in the horizontal direction H (only one of them is illustrated) and a plurality of electrodes arranged in the direction of the tube axis and located on the tube axis. The electrodes include a first grid electrode G1, a second grid electrode G2, a third grid electrode G3, a fourth grid electrode G4, a fifth grid electrode G5 (which serves as a focusing electrode), a sixth grid electrode G6 (which serves as a first intermediate electrode), a seventh grid electrode G7 (which serves as a second intermediate electrode), an eighth grid electrode G8 (which serves as a last accelerating electrode) and a convergence electrode CG. These electrodes are arranged from the cathodes K toward the phosphor screen 22 in the order mentioned.

The three cathodes K and the first to eighth grid electrodes G1 to G8 are supported by a pair of insulating support members, namely bead glasses 2. They are sandwiched in the vertical direction V and integrally held, with predetermined mutual positional relationships maintained. The convergence electrode CG is welded to the eighth grid electrode G8 and is electrically connected thereto.

Each of the first and second grid electrodes G1 and G2 is made by a comparatively thin plate electrode. Each of the third, fourth, fifth and eighth grid electrodes G3, G4, G5 and G8 is a cylindrical electrode obtained by integrally coupling a plurality of cup-shaped electrodes. Each of the sixth and seventh grid electrodes G6 and G7 is made by a comparatively thick plate electrode. Each grid electrode has electron beam passage holes through which the three electron beams from the three cathodes K pass.

A resistor 4 is arranged in the neighborhood of the electron gun assembly 26. The resistor 4 is located on one side of the electron gun assembly 26 and extends in the longitudinal direction of the bead glasses 2. The resistor 4 divides a high voltage based on a predetermined voltage division ratio, and voltages obtained thereby are applied to the grid electrodes. One end (the high-voltage end) of the resistor 4 is connected to the eighth grid electrode G8 by means of a lead-out terminal 6. The other end (the low-voltage end) of the resistor 4 is connected to a stem pin 8A by means of a lead-out terminal 7. Stem pins 8A and 8B penetrate a stem portion ST (which hermetically seals one end of the neck 24), without affecting the hermetically sealed state of the interior of the tube. In the outside of the tube, stem pin 8A is grounded directly or by way of a variable resistor. The resistor 4 has three lead-out terminals 5A, 5B and 5C at an intermediate portion thereof. Lead-out terminals 5A, 5B and 5C are arranged from the aforesaid one end in the order mentioned. Lead-out terminals 5A, 5B and 5C are connected to the seventh, sixth and fifth grid electrodes G7, G6 and G5, respectively.

The cathodes K and the grid electrodes of the electron gun assembly 26 are applied with predetermined voltages by way of stem pins 8B. To be more specific, the cathodes K are applied with a voltage obtained by superimposing an image signal onto a DC voltage of about 190V. The first grid electrode G1 is grounded. The second grid electrode G2 is applied with a DC voltage of about 800V. The third grid electrode G3 and the fifth grid electrode G5 are electrically connected to each other by means of a lead 3 inside the tube. The fourth grid electrode G4 is applied with a dynamic focus voltage obtained by superimposing an AC component voltage (which varies in a parabolic way in synchronism with the deflection of an electron beam) onto a DC voltage of about 8 to 9 kV.

The eighth grid electrode G8 is applied with an anode voltage of about 30 kV. The convergence electrode CG, which is welded to the eighth grid electrode G8, comprises a plurality of conduction springs 10 pressed against the internal conductive film 28. The anode voltage is applied to the convergence electrode CG and eighth grid electrode G8 by way of the anode terminal 27 provided for the funnel 21, the internal conductive film 28 and the conduction springs 10.

The anode voltage is applied to the resistor 4 as well, through the lead-out terminal 6 electrically connected to the convergence electrode CG. The seventh grid electrode G7, the sixth grid electrode G6 and the fifth grid electrode G5 are applied with voltages obtained by the voltage division based on a predetermined voltage division ratio, and the voltages are applied by way of the lead-out terminals 5A, 5B and 5C of the resistor 4. For example, the voltage applied to the sixth grid electrode G6 is about 35 to 45% of an anode voltage of 25 to 35 KV. The voltage applied to the seventh grid electrode G7 is about 50 to 70% of that anode voltage.

By applying the aforesaid voltages to the grid electrodes of the electron gun assembly 26, the cathode K, the first grid electrode G1 and the second grid electrode G2 jointly constitute an electron beam generation section for generating electron beams. The second grid electrode G2 and the third grid electrode G3 jointly constitute a pre-focus lens for pre-focusing the electron beams generated by the electron beam generation section.

The third grid electrode G3, the fourth grid electrode G4 and the fifth grid electrode G5 jointly constitute a sub lens that further focuses the electron beams pre-focused by the pre-focus lens. The fifth grid electrode G5, the sixth grid electrode G6, the seventh grid electrode G7 and the eighth grid electrode G8 jointly constitute a main lens that finally focuses the electron beams focused by the sub lens, in such a manner that the electron beams are focused on the phosphor screen 22.

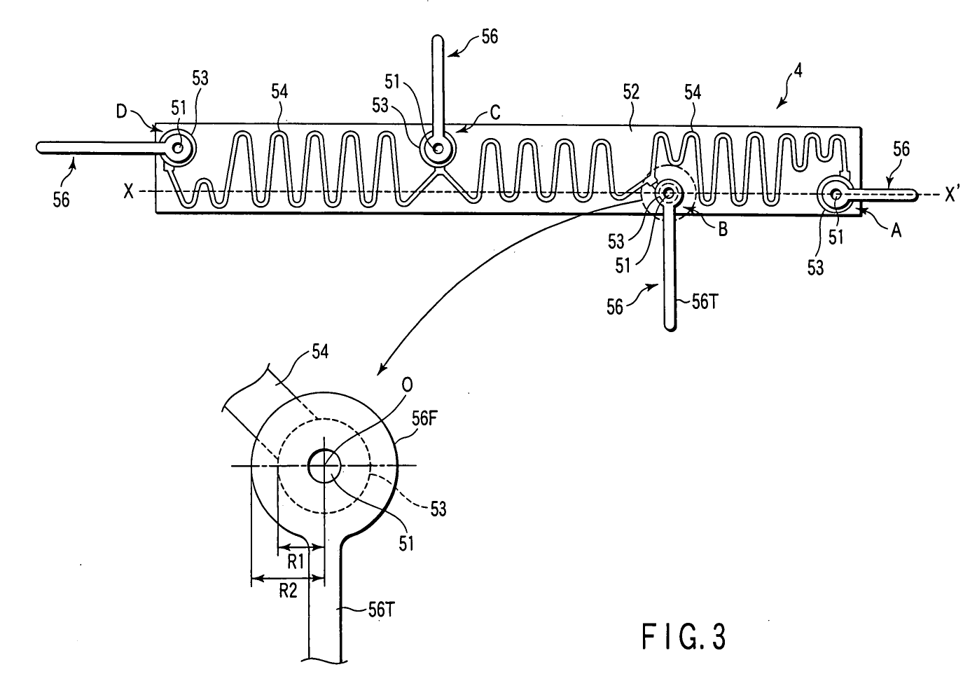

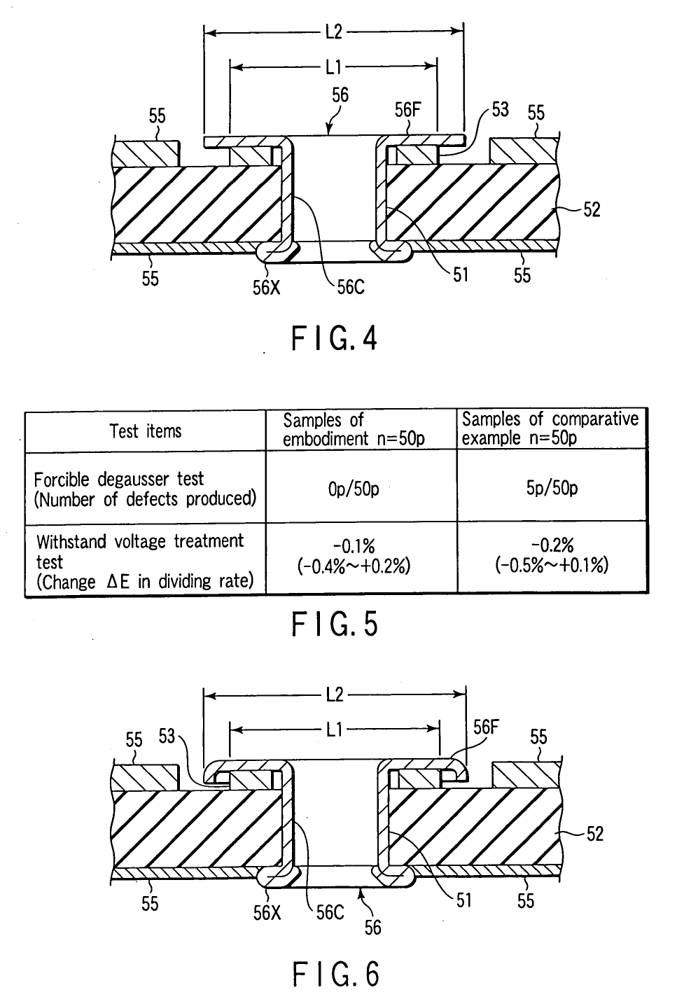

The structure of the resistor 4 will be described in more detail. As shown in FIGS. 3 and 4, the resistor 4 comprises: an insulating substrate 52; a plurality of electrode elements 53 (i.e., resistor elements for electrodes) formed on the insulating substrate 52; a resistor element 54 connecting the electrode elements together and providing a predetermined resistance value; an insulating coating layer 55 that covers the resistor element 54; and a plurality of metallic terminals 56 connected to the electrode elements 53.

The insulating substrate 52 is formed of a ceramic material mainly containing aluminium oxide. The insulating substrate 52 is shaped like a rectangular plate. The insulating substrate 52 has a plurality of through-holes 51 located at predetermined positions and formed from the obverse side to the reverse side. The through-holes 51 are at positions corresponding to terminal sections A to D.

The electrode elements 53 are formed of a comparatively low resistance material (e.g., a low-resistance paste material having a sheet resistance of 10 kΩ/□, for example) containing a metallic oxide (such as ruthenium oxide) and a glass material (such as borosilicic acid lead glass). The electrode elements 53 are arranged at predetermined positions on the surface of the insulating substrate 52. The electrode elements 53 are arranged like islands at the terminal sections A to D of the insulating substrate 52 and correspond to the through-holes 51 formed in the insulating substrate 52. The through-holes 51 are located substantially in the center of the electrode elements 53.

The resistor element 54 is formed of a material having a higher resistance than that of the electrode elements 53 (e.g., a high-resistance paste material having a sheet resistance of 5 kΩ/□, for example) containing a metallic oxide (such as ruthenium oxide) and a glass material (such as borosilicic acid lead glass). The resistor element 54 has a predetermined pattern (e.g., an undulating pattern) on the surface of the insulating substrate 52, and is electrically connected to the electrode elements 53. The length, width and thickness of the resistor element 54 are determined in such a manner that the resistor element 54 provides a predetermined resistance value between the electrode elements 53.

The insulating coating layer 55 is formed of a comparatively high resistance material mainly containing, for example, a transition metal oxide and borosilicic acid lead glass. The insulating coating layer 55 covers the obverse surface of the insulating substrate 52, including the resistor element 54, but does not cover the parts of the electrode elements 53. The insulating coating layer 55 covers the entire reverse surface of the insulating substrate 52 as well. With this structure, the withstand voltage characteristic of the resistor 4 is improved.

The interval between the electrode element 53 and the insulating coating layer 55 may be determined such that it is uniform at any portion of the outer periphery of each island-like electrode element 53. Alternatively, this interval may be determined in an imbalanced way such that it is short or zero in regions where a low voltage is applied (i.e., the electric discharge is less likely).

The metallic terminals 56 are formed of stainless steel, or metallic steel coated with a chromic oxide film, or the like. It is desirable that the metallic terminals 56 be formed of a nonmagnetic alloy since the use of this material does not give rise to adverse effects on the deflection magnetic field which is generated by the deflection yoke 29 or the electric field which is generated for the purpose of forming electron lenses in the electron gun assembly. For example, the metallic terminals 56 are formed of nonmagnetic stainless steel (e.g., an Fe—Ni—Cr alloy) whose relative permeability is not more than 1.01, preferably not more than 1.005.

Each metallic terminal 56 includes a flange 56F located at one end thereof, a tongue-like terminal piece 56T extending from the flange 56F, and a cylindrical portion 56C continuous with the flange 56F. The metallic terminal 56 is fixed to the insulating substrate by inserting the cylindrical portion 56C into the through-hole 51 from the obverse surface of the insulating substrate 52 and then corking the tip end 56X of the cylindrical portion 56C projected from the reverse surface of the insulating substrate 52. With this structure, each metallic terminal 56 is electrically connected to the corresponding electrode element 53, with this electrode element 53 interposed between the flange 56F and the insulating substrate 52. In this manner, the terminal sections A to D are formed.

Terminal section A is connected through the metallic terminal 56 to the lead-out terminal 6 and is applied with the highest voltage, namely, the anode voltage. Terminal section D is connected through the metallic terminal 56 to the lead-out terminal 7 and is applied with the lowest voltage (in this embodiment, terminal section D is grounded). Terminal section B is connected through the metallic terminal 56 to lead-out terminal 5A, for example, and is applied with the next highest voltage to the voltage applied to terminal section A. Terminal section C is connected through the metallic terminal 56 to lead-out terminal 5B, for example, and is applied with the next highest voltage to the voltage applied to terminal section B. In the example shown in FIG. 3, a terminal section connected to the lead-out terminal 5C is not illustrated for the sake of simplicity. Needless to say, however, a terminal section between terminal sections C and D may be provided.

(First Embodiment)

As shown in FIG. 4, the resistor 4 of the first embodiment satisfies the relationship L1≦L2, where L1 is an outer dimension of at least one of the electrode elements 53, and L2 is an outer dimension of the flange 56F of the metallic terminal 56 that is connected to the electrode element 53 whose outer dimension is L1. In the first embodiment, terminal section B to which the seventh grid electrode G7 is connected satisfies the relationship L2>L1, that is, the outer dimension L2 of flange 56F is greater than the outer dimension L1 of the electrode element 53. For example, the outer dimension L1 of the electrode element 53 is 0.8 mm, and is the outer dimension L2 of the flange 56F is 1.3 mm. In this case, the flange 56F is projected from the outer periphery of the electrode element 53, expands outward in parallel to the main surface of the insulating substrate 52, and covers the electrode element 53.

Where outer dimensions L1 and L2 satisfy L2>L1, the electrode element 53 is covered with the flange 56F. In this case, the peripheral portions of the electrode element 53 are not exposed. Even if glow discharge occurs between the electrode element 53 and a high-potential point, secondary electrons are not much emitted from the electrode element 53 because the flange 56F has portions located outward of the electrode element 53. In addition, the discharge current flows to the flange 56F, which is located close to the high-potential point, and does not directly flow to the electrode element 53. Accordingly, the discharge current at the time of the glow discharge does not damage the electrode element 53 or the insulating coating layer 55. Furthermore, voltages of desired values can be applied to the grid electrodes in a stable manner, thus maintaining the focus characteristics of the cathode ray tube.

Since the insulating coating layer 55 is not damaged and damaged pieces are not scattered, the clogging of the apertures of the shadow mask 23 is prevented. In addition, since the outer peripheral portions of the electrode element 53, which may be a starting point of glow discharge, are covered, the glow discharge due to the use of the resistor 4 can be suppressed. Furthermore, the current flowing at the time of glow discharge does not damage the resistor element 54. Hence, the resistor element 54 does not break or undergo other undesirable phenomena.

The advantages of the resistor 4 having the structure of the first embodiment were inspected. For this inspection, a cathode ray tube incorporating the resistor 4 having the structure shown in FIG. 4 (an embodiment of the present invention) and a cathode ray tube incorporating a conventional resistor (a comparative example) were prepared, and a forcible degausser test was carried out using these two cathode ray tubes. The conventional resistor of the comparative example satisfied the relationship L2<L1. More specifically, in the resistor of the comparative example, the outer dimension L2 of the flange was 1.3 mm, and the outer dimension L1 of the electrode element was 1.5 mm. The outer peripheral portion of the electrode element was projected from the flange and exposed.

The forcible degausser test is a test wherein an intense magnetic field is forcibly applied to the electron gun assembly from outside the cathode ray tube, so as to intentionally cause glow discharge. Where the glow discharge comes to an end, the cathode ray tube is regarded as a satisfactory product. Where the glow discharge continues, the cathode ray tube is rejected as a defective product.

A withstand voltage treatment test was also carried out to measure the rate ΔE at which the voltage division ratio changed before and after the withstand voltage treatment. The forcible degausser test and the withstand voltage treatment test were effected with respect to 50 samples of the embodiment and 50 samples of the comparative example. Results of these tests are shown in FIG. 5.

As shown in FIG. 5, in the forcible degausser test, none of the samples of the embodiment were defective, but the continuation of glow discharge was observed in five out of the 50 samples of the comparative example.

With respect to the samples of the embodiment, the withstand voltage treatment test showed that the rate ΔE of the division ratio was within the range of −0.4% to +0.2%, and that the average of the rate ΔE was −0.1%. With respect to the samples of the comparative example, the rate ΔE of the division ratio was within the range of −0.5% to +0.1%, and that the average of the rate ΔE was −0.2%. In the withstand voltage treatment test, the samples of the embodiment bore comparison with the samples of the comparative example. It was therefore confirmed that the samples of the embodiment (for which measures for preventing glow discharge were taken) showed satisfactory withstand voltage characteristics like those of the samples of the comparative example. In other words, the measures for preventing glow discharge did not have any adverse effects on the performance and characteristics.

As described above, the structure wherein the flange 56F shields the electrode element 53 suppressed the occurrence of glow discharge. To make this advantage more reliable, the structure shown in FIG. 6 may be adopted. As shown in FIG. 6, the tip of the flange 56F, which is projected outwardly from the electrode element 53, may be curved in such a manner as to cover the electrode element 53. In this case, the outer dimension L2 of the flange 56F and the outer dimension L1 of the electrode element 53 maintain the relationship L2>L1, and the outer periphery of the flange section 56F is curved toward the outer periphery of the electrode element 53.

As described above, even the outer periphery of the electrode element 35 can be shielded (covered) by curving the outer periphery of the flange 56F toward the insulating substrate 52. If the tip end of the flange 56F is curved in such a manner that the curved portion have a dimension corresponding to the thickness of the electrode element 53 and the outer periphery of the flange 56F is in contact with the insulating substrate 52, the electrode element 53 can be completely covered and shielded from the outside.

With this structure, the glow discharge at the electrode element 53 can be suppressed more reliably, and the metallic terminal 56 can be fixed tightly. It should be noted that the operation of curving the flange 56F can be performed simultaneously with the operation of corking the tip end 56X of the metallic terminal 56. Hence, no additional step is required at the time of manufacture.

In the above description, reference was made to the case where L2>L1. However, the outer dimension L2 of the flange may be substantially equal to the outer dimension L1 of the electrode element, if so desired. In this case as well, the glow discharge can be suppressed.

(Second Embodiment)

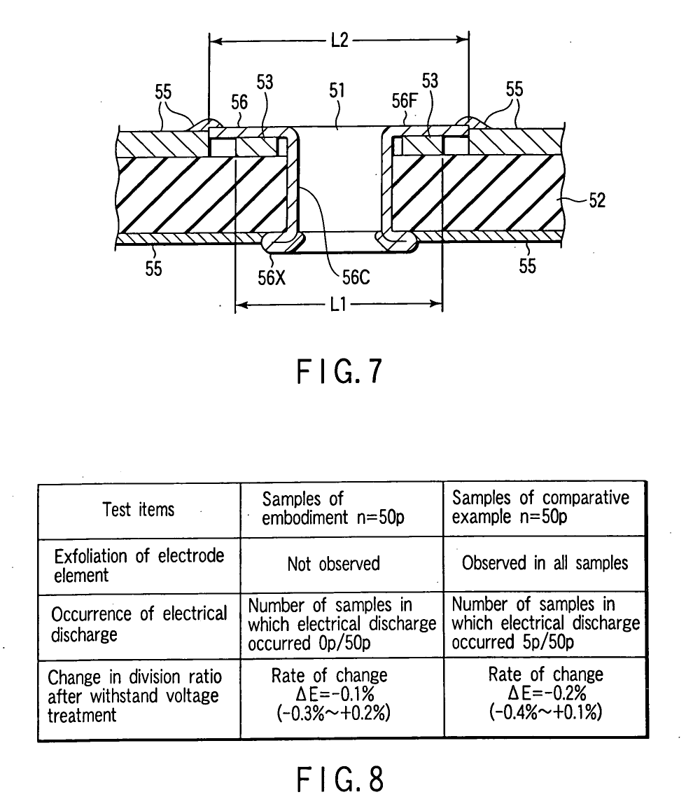

In the resistor 4 according to the second embodiment, as shown in FIG. 7, the metallic terminal 56 is provided without exposing the electrode element 53. Furthermore, the insulating coating layer 55 is not in contact with the electrode element 53 and yet covers the outer periphery of the metallic terminal 56.

More specifically, the flange 56F of the metallic terminal 56 is in contact with the electrode element 53 and has a greater outer dimension L2 than that L1 of the electrode element 53. In other words, the flange 56F includes portions located outward of the outer periphery of the electrode element 53, and thus covers the electrode element 53. With this structure, the flange 56F of the metallic terminal 56 is laid over the electrode element 53 and covers the entire surface of the electrode element 53. Hence, the surface of the electrode element 53 is not exposed.

The insulating coating layer 55 covers the periphery of the flange 56F of the metallic terminal 56. It should be noted that the insulating coating layer 55 does not include a portion located at a position corresponding to the outer dimension L2 of the flange section 56F. When the metallic terminal 56 is provided, the insulating coating layer 55 does not exist between the flange 56F and the insulating substrate 52. Since the electrode element 53 has an outer dimension L1 smaller than the outer dimension L2 of the flange 56F, it is not in contact with the insulating coating layer 55. Furthermore, since the insulating coating layer 55 does not exist at a position corresponding to the outer dimension L2 of the flange 56F, there is no gap between the flange section 56F and the insulating coating layer 55. With this structure, the surface portion of the insulating substrate 52 located between the electrode element 53 and the insulating coating layer 55 is covered with the flange 56F, and the insulating substrate 52 is not exposed at the terminal section and its neighboring portions.

In the examples shown in FIGS. 3 and 7, the electrode element 53 forms a doughnut shape and has first radius R1 (e.g., about 0.8 mm) as measured from the center O of the through-hole 51 of the insulating substrate 52. The flange 56F of the metallic terminal 56 also forms a doughnut shape and has second radius R2 (e.g., about 1.3 mm) as measured from the center O of the through-hole 51, and the second radius R2 is greater than the first radium R1. In this state, all the periphery of the flange 56F of the metallic terminal 56 is covered with the insulating coating layer 55. Hence, the surface of the insulating substrate 52 is completely covered.

With the above structure, the periphery of the electrode element 53 (i.e., the edge of the electrode element 53) is not projected from under the metallic terminal 56. In addition, the insulating coating layer 55 is not in contact with the electrode element 53; it is located away from the electrode element 53. Even when a high voltage is applied in a highly vacuum state, no triple function is formed, and the electrode element 53 does not have any portion where an electric field is concentrated.

Therefore, exfoliation does not occur in any of the electrode element 53, the metallic terminal 56 which is in contact therewith, and the insulating coating layer 55 which covers part of the metallic terminal 56. In addition, the resistor element 54 connected to the electrode element 53 is not damaged. Furthermore, electrical discharge which would occur due to an electrode element portion that remains after exfoliation is suppressed.

The insulating coating layer 55 covers the periphery of the metallic terminal 56 that covers the electrode element 53. This structure is effective in reducing the exposed area of the insulating substrate 52. The insulating substrate 52 is completely covered by providing the insulating coating layer 55 in such a manner as to cover all the periphery of the metallic terminal 56. Thus, the surface of the insulating substrate 52, from which secondary electrons may be emitted, is completely covered, thereby suppressing the occurrence of the electrical discharge.

A method for manufacturing the resistor 4 will be described.

First of all, an insulating substrate 52 having through-holes 51 at predetermined positions is prepared. A low-resistance paste material is coated on the insulating substrate 52 by screen printing. The screen used then has a pattern that enables doughnut-shaped electrode elements 53 to be formed like islands in correspondence to the through-holes 51. Subsequently, the coated low-resistance paste material is dried and fired. As a result, a plurality of electrode elements 53 are formed.

Thereafter, a high-resistance paste material is coated on the insulating substrate 52 by screen printing. The screen used then has a pattern connected to the island-like electrode elements 53 and providing a predetermined resistance between the electrode elements 53. Subsequently, the coated high-resistance paste material is dried and fired. As a result, a resistor element 54 provides a predetermined resistance (e.g., a resistance in the range of 0.1×10⁹ to 2.0×10⁹Ω) for the entire resistor 4.

Next, an insulating coating layer 55 is coated on the entire insulating substrate 52 by screen printing in such a manner that the insulating coating layer 55 covers the resistor element 54 except at positions corresponding to the electrode elements 53 and their neighboring regions. The insulating coating layer 55 is dried and fired. The screen used then has a pattern having open sections corresponding to the outer shapes of the flanges 56F of metallic terminals 56, which are to cover the electrode elements 53.

Then, the cylindrical portion 56C of a metallic terminal 56 is inserted into a through-hole 51 from the obverse surface of the insulating substrate 52, and the tip end 56X of the cylindrical portion 56C projected from the reverse surface is corked. As a result, each metallic terminal 56 is electrically connected to the corresponding electrode element 53. The insulating substrate 52 exposed between the electrode element 53 and the insulating coating layer 55 is covered with the flange 56F. Therefore, the exposed area of the insulating substrate 52 is substantially zero.

In the step of forming the insulating coating layer 55, it is desirable that a margin greater than the outer dimension of the flange 56F be secured to cope with misalignment of screens. When the metallic terminals 56 are attached in this state, regions where the insulating substrate 52 is exposed will be produced around the flanges 56F. It is therefore desirable that the step of attaching the metallic terminals 56 be followed by the step of forming the insulating coating layer 55, so as to cover the periphery of each flange 56F with the insulating coating layer 55, as shown in FIG. 7. Since the exposed regions around the flanges 56F are completely covered with the insulating coating layer 55, the insulating substrate 52 is not exposed; it is completely covered with the insulating coating layer 55 (the exposed area can be substantially zero).

The resistor 4 is formed by following the above steps. In the resistor 4 that was manufactured, the aforesaid structure was applied to terminal B. Needless to say, the same structure may be applied to the other terminals as well.

The resistor 4 formed as above was incorporated in the cathode ray tube, and a withstand voltage treatment was carried out with respect to the cathode ray tube. After the withstand voltage treatment, a test was executed to see if the electrode elements 53 exfoliated, and if electrical discharge occurred. FIG. 8 shows results of the test. For this test, 50 resistors having the structure shown in FIG. 7 (i.e., resistors of the embodiment) and 50 resistors having the structure described in Jpn. Pat. Appln. KOKAI Publication No. 6-68811 (i.e., resistors of the comparative example) were prepared and checked.

As shown in FIG. 8, the exfoliation of the electrode elements 53 was observed in all 50 resistors of the comparative example. In contrast, the exfoliation of the electrode elements 53 was not observed in any of the 50 resistors of the embodiment. As for the electrical discharge, it occurred in five of the resistors of the comparative example, but did not occur in any of the resistors of the embodiment.

The rate ΔE at which the voltage division ratio changed before and after the withstand voltage treatment was also measured. The measurement showed that the rate ΔE varied in the range of −0.3% to +0.2% in the resistors of the embodiment, and that the average of the rate ΔE was −0.1%. With respect to the resistors of the comparative example, the rate ΔE varied in the range of −0.4% to +0.1%, and the average of the rate ΔE was −0.2%. The results of measurement were similar to those described above.

As described above, the electron gun assembly resistor of the embodiment is advantageous for use in a cathode ray tube because the electrode elements and the insulating coating layer 55 of the resistor do not exfoliate and the apertures of the shadow mask are not therefore clogged. In addition, the resistor enables stable voltage application inside the cathode ray tube and is therefore reliable.

In the above embodiment, the periphery of the flange 56F of the metallic terminal 56 is completely covered, but the advantages of the present invention can be expected even where that periphery is partly covered. In other words, the surface of the insulating substrate 52 should be covered with the insulating coating layer 55 at least at surface portions that are electrically charged to have a potential higher than that of the metallic terminals. This is because the metallic terminal 56 is likely to function as a cathode where electrical discharge occurs in the neighborhood of a metallic terminal 56 inside the cathode ray tube. If the metallic terminal 56 functions as a cathode, electrons may hop on the charged surface of the insulating substrate, resulting in emission of secondary electrons. This phenomenon is reliably suppressed-by-covering the insulating substrate 52 at surface portions where high voltage is applied.

The above embodiment was described, referring to the case where the resistor was applied to a color cathode ray tube apparatus. However, the present invention is not limited to this. Needless to say, the present invention is applicable to an electron gun assembly whose grid electrode structure differs from that described above, and the resistor of the above structure is applicable to another type of electron tube requiring a voltage-dividing resistor.

The insulating substrate is not limited to a rectangular shape. It may be square to make it correspond to the space of the cathode ray tube. In light of the space factor of the insulating substrate, resistor elements may be formed on the two sides of a substrate and electrically connected to each other by means of a through pin or the like. In this case, a pattern arrangement can be performed with a high degree of freedom and the substrate can be small.

The insulating substrate and the insulating support members (bead glasses) may be realized by one member. In addition, the cylindrical member of the electrode terminal described above may be replaced with a member having a desirable shape, such as a forked hook member or a quadratic prism member.

The present invention is not limited to the embodiment described above, and may be modified in various ways without departing from the spirit and scope of the invention. Embodiments or modifications of the present invention may be combined when they are reduced to practice, and advantages obtained then are unique to the combinations.

As described above, the present invention can provide an electron gun assembly resistor which is not damaged even when a high voltage is applied and which is reliable in performance. The present invention can also provide a cathode ray tube incorporating that electron gun assembly resistor.

What is claimed is:

1. An electron gun assembly resistor comprising:
an insulating substrate;
a plurality of electrode elements formed on the insulating substrate and looking like islands;
a resistor element connecting the electrode elements together and providing a predetermined resistance value; and
a plurality of metallic terminals which include flanges in contact with the electrode elements, and which are connected to the electrode elements,
the electron gun assembly resistor satisfying
L1≦L2,
where L1 is an outer dimension of at least one of the electrode elements, and L2 is an outer dimension of the flange of the metallic terminal that is connected to the electrode element whose outer dimensions is L1.

2. An electron gun assembly resistor according to claim 1, wherein the flanges are located outward of outer peripheries of the electrode elements.

3. An electron gun assembly resistor according to claim 1, wherein the flanges include tip ends that are curved to cover the electrode elements.

4. A comprising:
a face panel;
a funnel integrally connected to the face panel;
a phosphor screen formed on an inner surface of the face panel;
an electron gun assembly arranged in a neck of the funnel, configured to emit electron beams toward the phosphor screen, and including a plurality of grid electrodes; and
an electron gun assembly resistor arranged in the neck and juxtaposed to the electron gun assembly, the electron gun assembly resistor dividing a voltage based on a predetermined voltage division ratio and permitting a divided voltage to be applied to at least one of the grid electrodes,
the electrode gun assembly resistor comprising:
an insulating substrate;
a plurality of electrode elements formed on the insulating substrate and looking like islands;
a resistor element connecting the electrode elements together and providing a predetermined resistance value; and
a plurality of metallic terminals which include flanges in contact with the electrode elements, and which are connected to the electrode elements,
the electron gun assembly resistor satisfying
L1≦L2,
where L1 is an outer dimension of at least one of the electrode elements, and L2 is an outer dimension of the flange of the metallic terminal that is connected to the electrode element whose outer dimension is L1.

5. A cathode ray tube according to claim 4, wherein the flanges are located outward of outer peripheries of the electrode elements.

6. An electron gun assembly resistor according to claim 4, wherein the flanges include tip ends that are curved to cover the electrode elements.

7. An electron gun assembly resistor configured to divide a voltage based on a predetermined voltage division ratio and to permit a divided voltage to be applied to an electrode of an electron gun assembly, the electron gun assembly resistor comprising:
an insulating substrate;
a plurality of electrode elements formed on the insulating substrate;
a resistor element connecting the electrode elements together and providing a predetermined. resistance value;
an insulating coating layer which covers the resistor element; and
a plurality of metallic terminals connected to the electrode elements, respectively,
the metallic terminals being arranged without exposing the electrode elements,
the insulating coating layer being coated on peripheries of the metallic terminals and being located away from the electrode elements.

8. An electron gun assembly resistor according to claim 7, wherein regions where the insulating coating layer covers the peripheries of the electrode elements are regions where the insulating substrate has surface portions that are electrically charged to have a potential higher than that of the metallic terminals.

9. An electron gun assembly resistor according to claim 7, wherein the metallic terminals include flanges which are in contact with the electrode elements, and the flanges have an outer dimension greater than that of the electrode elements and include portions located outward of the peripheries of the electrode elements.

10. An electron gun assembly resistor according to claim 9, wherein the insulating coating layer covers the peripheries of the flanges of the metallic terminals without exposing the insulating substrate.
